(19) United States
(12) Patent Application Publication
(10) Pub. No.: US 2009/0102501 A1
(43) Pub. Date: Apr. 23, 2009

(54) TEST STRUCTURES FOR E-BEAM TESTING OF SYSTEMATIC AND RANDOM DEFECTS IN INTEGRATED CIRCUITS

(76) Inventors: Richard L. Guldi, Dallas, TX (US); Toan Tran, Rowlett, TX (US); Deepak Ramappa, Dallas, TX (US); Steven A. Lytle, McKinney, TX (US)

Correspondence Address: TEXAS INSTRUMENTS INCORPORATED, P O BOX 655474, M/S 3999, DALLAS, TX, 75265, US

(21) Appl. No.: 11/875,185

(22) Filed: Oct. 19, 2007

(51) Int. Cl. G01N 23/225; G01R 31/26

(52) U.S. Cl. 324/765; 250/310

(57) ABSTRACT

In accordance with the invention, there are electron beam inspection systems, electron beam testable semiconductor test structures, and methods for detecting systematic defects, such as, for example contact-to-gate shorts, worm hole leakage paths, holes printing issues, and anomalies in sparse holes and random defects, such as, current leakage paths due to dislocations and pipes during semiconductor processing.

### FIELD OF THE INVENTION

The subject matter of this invention relates to fabricating a semiconductor device. More particularly, the subject matter of this invention relates to methods and structures for e-beam testing of systematic and random defects in integrated circuits.

### BACKGROUND OF THE INVENTION

Competitive yield learning requires defect characterization and rapid resolution of systematic and random defect issues during early integrated circuit development. E-beam testing provides high sensitivity assessment as well as the ability to localize defects for cross-sectioning. Hence, there is a need for E-beam testable structures to characterize known systematic defect issues occurring in, for example, in 45 nm technology, such as contact-to-gate shorts, worm hole leakage paths, contact printing issues, and sparse hole processing.

E-beam has also been used for inspection of random defects such as, dislocations on product wafers and has provided a means of quantifying dislocation density with short cycle time. Traditionally, dislocation inspections have been done using static random access memory (SRAM) structures. However, the detection sensitivity of e-beam inspection is compromised by the lack of a substrate ground in close proximity to SRAM elements. In addition, as process improvements are made, the SRAM cells become less sensitive indicators of the tendency to form dislocations so that it is difficult to assess the impact of design of experiments (DOEs) for further dislocation density reduction. Therefore, a set of structures is needed to provide greater sensitivity to dislocation formation so that remedial DOEs can be more successfully evaluated.

Accordingly, there is a need to overcome these and other problems of the prior art to provide methods and structures for e-beam testing of dislocations, pipes, and electrical leakage.

### SUMMARY OF THE INVENTION

In accordance with the invention, there is a method for detecting a defect during semiconductor processing. The method can include providing a semiconductor test structure and directing an electron beam at the semiconductor test structure. The method can also include detecting emissions from the semiconductor test structure, determining a gray level value (GLV) from the emissions, and identifying a defect by the determined GLV.

According to another embodiment of the present teachings, there is a semiconductor test structure for detecting current leakage paths. The semiconductor test structure can include one or more design elements accentuating localized, non-uniform stress in a semiconductor device, selected from the group consisting of active layer jogs, double active jogs with asymmetry, multiple active jogs, gate electrode turns over field dielectric regions, and H gate electrode turns over field dielectric regions. The semiconductor test structure can also include a substrate ground in close proximity to an active region including one or more of remote substrate grounds and substrate ground regions proximate to the active region.

According to yet another embodiment of the present teachings, there is a semiconductor test structure for detecting a contact-to-gate short including a p-type substrate, a plurality of floating gate electrodes, a plurality of grounded contacts through a dielectric layer, wherein a contact to gate electrode line spacing is less than or equal to a design rule, and a plurality of metal pads over the dielectric layer.

According to another embodiment of the present teachings, there is a semiconductor test structure for detecting a worm-hole. The semiconductor test structure can include a p-type substrate including a plurality of n-type active regions; a plurality of gate electrodes, wherein a gate electrode to gate electrode spacing is less than or equal to a design rule; a plurality of contacts through a dielectric layer; and a plurality of alternating grounded/floating rows of metal pads over the dielectric layer.

According to yet another embodiment of the present teachings, there is a semiconductor test structure for detecting troublesome pitches for hole printing during semiconductor processing. The semiconductor test structure can include a p-type substrate, a dielectric layer over the substrate, an array of grounded holes through the dielectric layer having a desired troublesome pitch, wherein the troublesome pitch is determined by one or more of an exposure conditions modeling and an empirical data, and a plurality of metal pads over the dielectric layer.

Additional advantages of the embodiments will be set forth in part in the description which follows, and in part will be obvious from the description, or may be learned by practice of the invention. The advantages will be realized and attained by means of the elements and combinations particularly pointed out in the appended claims.

It is to be understood that both the foregoing general description and the following detailed description are exemplary and explanatory only and are not restrictive of the invention, as claimed.

The accompanying drawings, which are incorporated in and constitute a part of this specification, illustrate embodiments of the invention and together with the description, serve to explain the principles of the invention.

### BRIEF DESCRIPTION OF THE DRAWINGS

FIGS. 1-7 illustrate a plan view of a portion of various exemplary semiconductor test structures, according to various embodiments of the present teachings.

FIG. 8 illustrates an exemplary system for detecting a current leakage path defect generation during semiconductor processing, according to various embodiments of the present invention.

FIG. 9 depicts a flow diagram of an exemplary method for detecting a current leakage path defect during semiconductor processing, according to various embodiments of the present teachings.

FIG. 10 illustrates a plan view of a portion of an exemplary semiconductor test structure for detecting a contact-to-gate short in accordance with the present teachings.

FIG. 11 depicts a flow diagram of an exemplary method for detecting a contact-to-gate short during semiconductor processing, according to various embodiments of the present teachings.

FIG. 12 illustrates a plan view of a portion of another exemplary semiconductor test structure for detecting a contact-to-gate short in accordance with the present teachings.

FIG. 13 depicts a flow diagram of another exemplary method for detecting a contact-to-gate short during semiconductor processing, according to various embodiments of the present teachings.

FIG. 14 illustrates a plan view of a portion of an exemplary semiconductor test structure for detecting a worm hole in accordance with the present teachings.

FIG. 15 depicts a flow diagram of an exemplary method for detecting a worm hole during semiconductor processing, according to various embodiments of the present teachings.

FIGS. 16A and 16B illustrate a plan view of a portion of exemplary semiconductor test structures for detecting troublesome pitches in accordance with the present teachings.

FIG. 17 depicts a flow diagram of an exemplary method for detecting a troublesome pitch during semiconductor processing, according to various embodiments of the present teachings.

FIG. 18 illustrates a plan view of a portion of an exemplary semiconductor test structure for detecting anomalies in semi-isolated contacts in accordance with the present teachings.

FIG. 19 depicts a flow diagram of an exemplary method for detecting anomalies in semi-isolated contacts during semiconductor processing, according to various embodiments of the present teachings.

### DESCRIPTION OF THE EMBODIMENTS

Reference will now be made in detail to the present embodiments, examples of which are illustrated in the accompanying drawings. Wherever possible, the same reference numbers will be used throughout the drawings to refer to the same or like parts.

Notwithstanding that the numerical ranges and parameters setting forth the broad scope of the invention are approximations, the numerical values set forth in the specific examples are reported as precisely as possible. Any numerical value, however, inherently contains certain errors necessarily resulting from the standard deviation found in their respective testing measurements. Moreover, all ranges disclosed herein are to be understood to encompass any and all sub-ranges subsumed therein. For example, a range of “less than 10” can include any and all sub-ranges between (and including) the minimum value of zero and the maximum value of 10, that is, any and all sub-ranges having a minimum value of equal to or greater than zero and a maximum value of equal to or less than 10, e.g., 1 to 5. In certain cases, the numerical values as stated for the parameter can take on negative values. In this case, the example value of range stated as “less that 10” can assume negative values, e.g. −1, −2, −3, −10, −20, −30, etc.

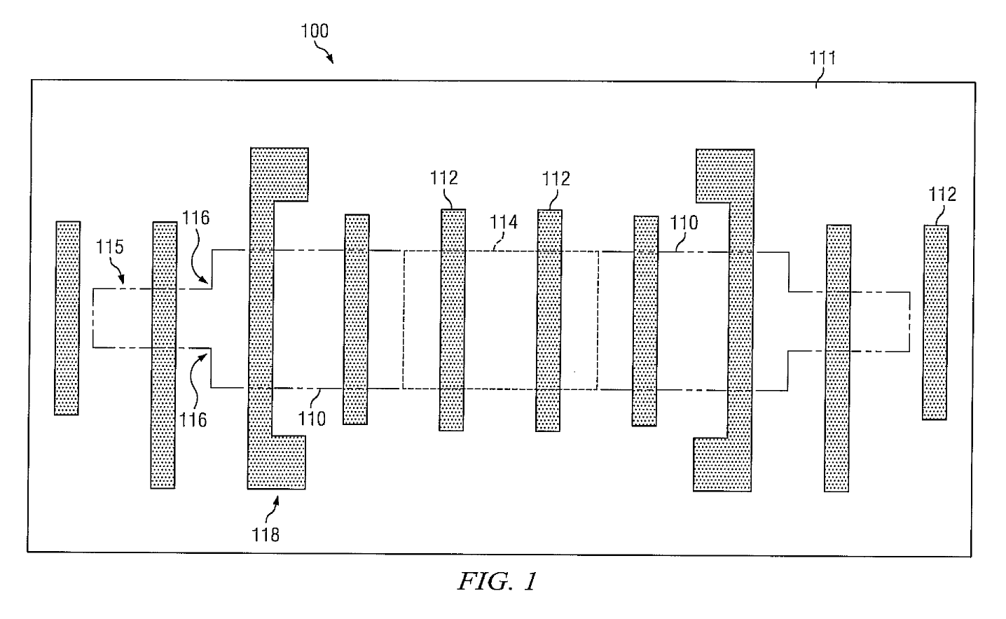

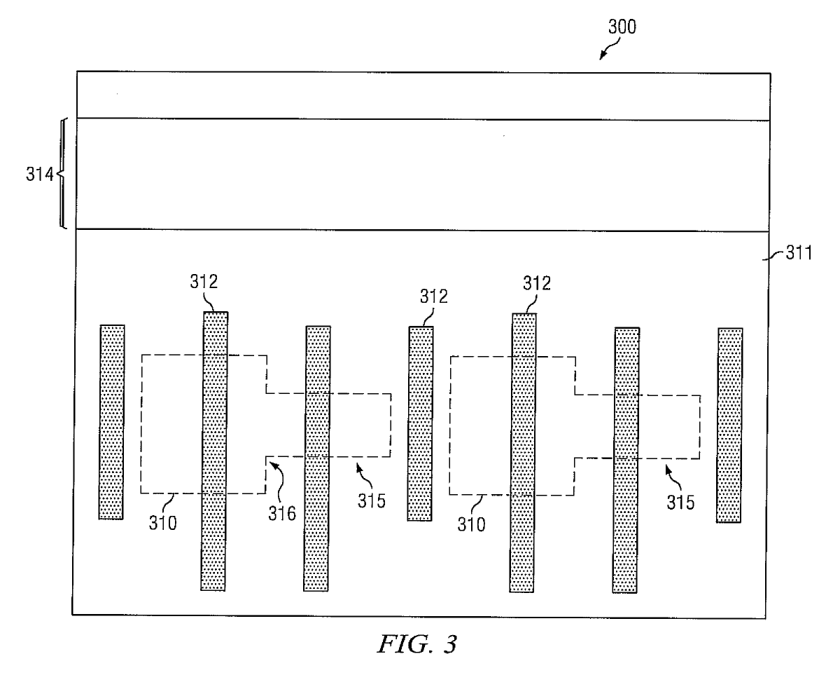

FIGS. 1-7 illustrate a portion of various exemplary semiconductor test structures 100-700, according to various embodiments of the present teachings. The semiconductor test structures 100-700 can include one or more design elements that accentuate localized, non-uniform stress in a semiconductor device, such as, for example, active layer jogs 115, 215, 315, 415, double active jogs with asymmetry 515, multiple active jogs 615, 715, gate electrode turns over field dielectric regions 118, 218, 418, and H gate electrode structures turns on field dielectric regions 518, 618, 718, as shown in FIGS. 1-7. The semiconductor test structures 100-700 can also include a substrate ground 114, 214, 414, 514, 614, 714 in close proximity to an active region 110, 210, 310, 410, 510, 610, 710 including one or more of remote well grounds 314 as shown in FIG. 3 and well ground regions preserving gate electrode 112 periodicity as shown in FIGS. 1, 2, 4-7. In various embodiments, a field oxide layer 111, 211, 311, 411, 511, 611, and 711 can be around the active region 110, 210, 310, 410, 510, 610, 710 layer in order to define the active region 110, 210, 310, 410, 510, 610, 710 and to also electrically isolate the various active regions 110, 210, 310, 410, 510, 610, 710 from each other. One of ordinary skill in the art would know that immersion lithography requires that parallel gate electrodes be separated by a specific range of spacings in order to achieve good linewidth integrity.

FIG. 1 illustrates a portion of an exemplary semiconductor test structure 100 including an active region jog 115 at a center of an active region 110, also referred to as a T-jog. As used herein, the term “jog” refers to turns, constrictions, and expansions in the active region, such as, for example, protrusions, indentations, staircase, etc. As shown in FIG. 1, the active region jog 115 includes a centrally positioned protrusion, which can create high stress at corners 116. In various embodiments, the active region 110 can be formed of silicon, gallium arsenide, or other semiconductor material. The semiconductor structure 100 can also include one or more gate electrodes 112, extending over the active region 110 from one edge to another. In various embodiments, the gate electrodes 112 can be formed of one or more of polysilicon, metal, and/or metal silicide. In some embodiments, the ends of the gate electrode 112 can be bent at 90° to form “gate electrode turns over field dielectric regions” 118, wherein the bent gate electrode 118 of the gate electrode 112 can be in close proximity to the active region 110, as shown in FIG. 1. In various embodiments, the separation between the gate electrode turns over field dielectric regions 118 and the active region 110 can be from about 10 nm to about 100 nm. The smaller the separation between the gate electrode turns over field dielectric regions 118 and the active region 110, the more stress can be created in the active region, thereby making it more susceptible to current leakage path defect generation. The semiconductor test structure 100 can also include a substrate ground region 114 in close proximity to the active region 110, as shown in FIG. 1. In the exemplary semiconductor test structure 100, as shown in FIG. 1, the active region 110 is a ground. In various embodiments, the substrate ground region 114 can be a heavily doped p-contact region including p-type dopants, such as, for example, boron in order to make a good electrical contact to the p-type silicon substrate. As can be seen in FIG. 1, one or more gate electrodes 112 can be extended over the substrate ground region 114 and the active region 110 onto the field oxide region 111. For a p-type silicon substrate, the source and the drain of a transistor can be n-type doped by, for example, phosphorus, arsenic, and/or antimony. Since n-type dopants such as, for example, arsenic and antimony are much bigger in size as compared to p-type dopant boron, n-type dopants can cause more stress and can be more likely to produce current leakage paths. In various embodiments, the substrate can be n-type, the substrate ground region 114 can be a heavily doped n-type region including n-type dopants, and the source and the drain of a transistor can be doped p-type.

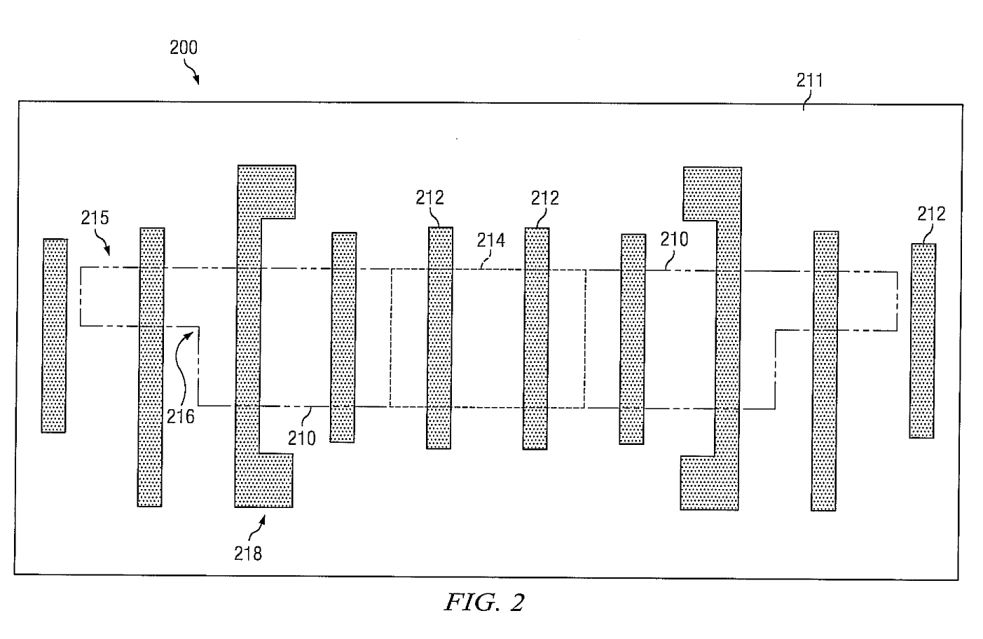

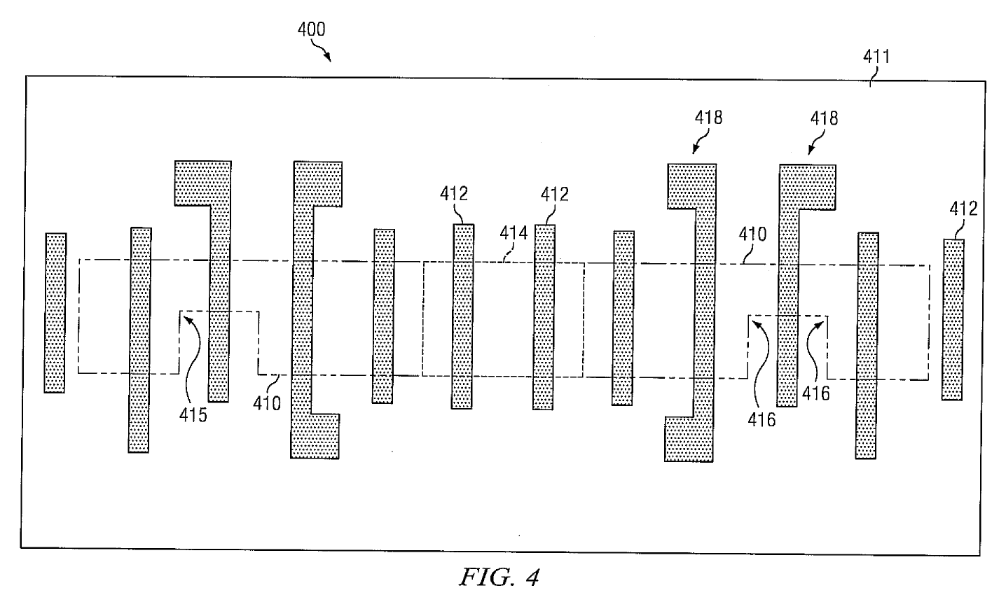

FIG. 2 illustrates a portion of an exemplary semiconductor test structure 200 including one or more L-jogs 215, each of Which includes an active region jog 215 at an edge of an active region 210 and high stress corners 216 of the active region 210; one or more gate electrodes 212; one or more gate electrode turns over field dielectric regions 218; substrate ground region 214 in close proximity to the active region 210 and preserving gate electrode 212 periodicity. In various embodiments, one or more gate electrodes 212 can be extended over the substrate ground region 214 and the active region 210 onto the field oxide region 211. FIG. 3 is another embodiment of the present teachings wherein the semiconductor structure 300 includes one or more T-jogs 315, each of which includes an active region jog 315 approximately at the center of an active region 310, one or more gate electrode 312 extended over the active region 310 onto the field oxide region 311, and one or more remote substrate grounds 314. In some embodiments, the semiconductor structure 300 can also include one or more gate electrode turns over field dielectric regions (not shown). FIG. 4 illustrates a portion of another exemplary semiconductor test structure 400 including one or more U-shaped active region jogs 415 in an active region 410, high stress corners 416 of the active region 410, one or more gate electrodes 412 extended over the active region 410 onto the field oxide region 411, one or more gate electrode turns over field dielectric regions 418, substrate ground region 414 in close proximity to the active region 410 and preserving the gate electrode 412 periodicity.

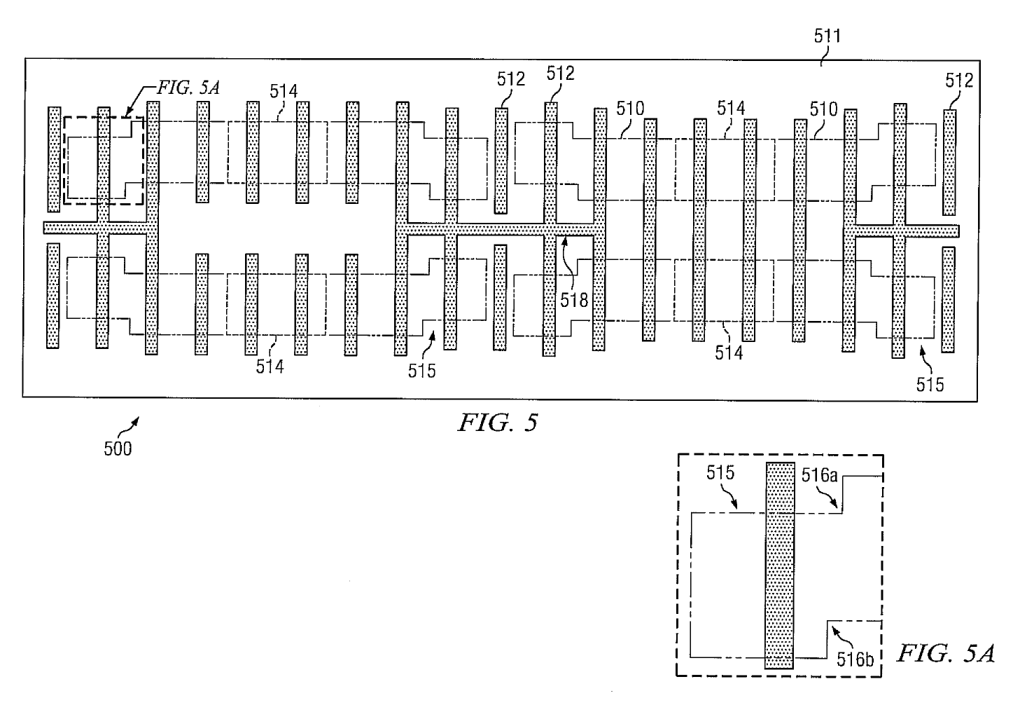

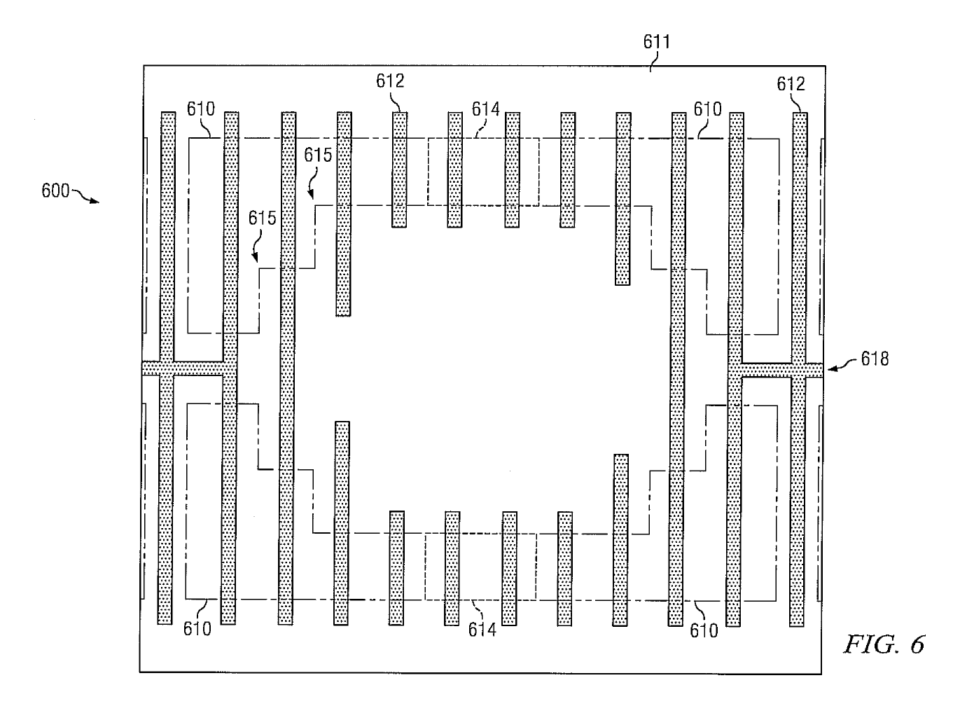

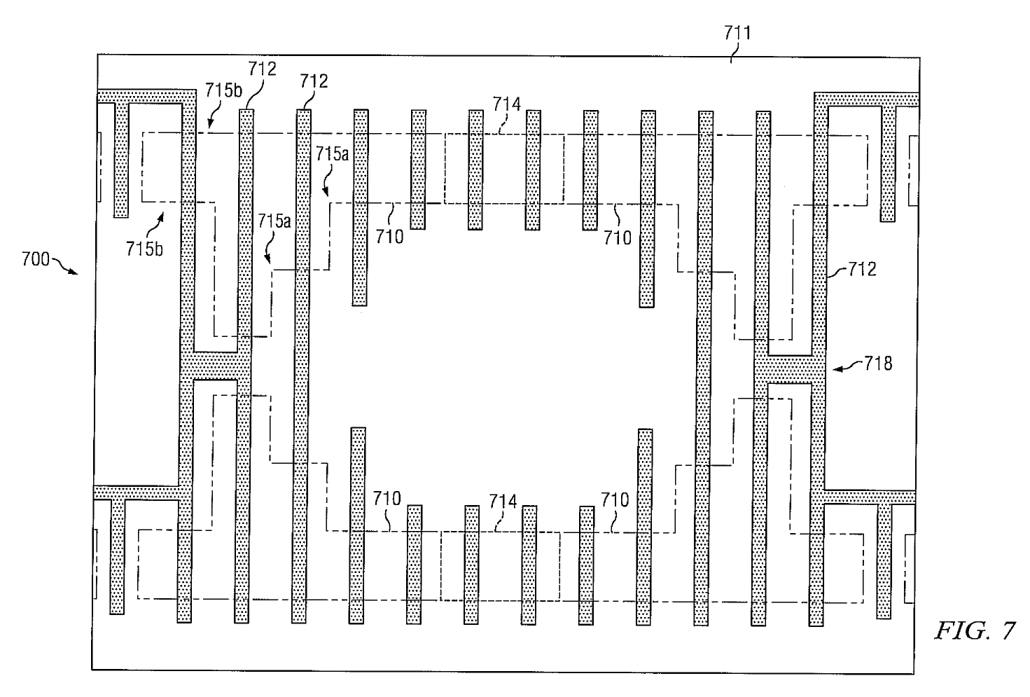

FIG. 5 illustrates a portion of an exemplary semiconductor test structure 500 including one or more asymmetric active region jogs 515 in an active region 510, high stress corners 516a and 516b of the active region 510 and one or more gate electrodes 512 extended over the active region 510 onto the field oxide region 511. The semiconductor test structure 500 can also include one or more gate electrodes 512 arranged in an H-pattern around the asymmetric active region jogs 515, thereby making an H gate electrode turns over field dielectric region 518. The semiconductor test structure 500 can further include a substrate ground region 514 in close proximity to the active region 510 which can also preserve the gate electrode 512 periodicity. As shown in the FIG. 5A, a blown up view of a part of FIG. 5, the asymmetric active jog region 515 includes corners 516a and 516b that can be of dissimilar size and shape. FIG. 6 illustrates another exemplary semiconductor test structure 600 including one or more multiple active jogs 615 such as, for example, staircase active region jogs 615, one or more gate electrodes 612 extended over the active region 610 onto the field oxide region 611, one or more H gate electrode turns over field dielectric region 618, and a substrate ground region 614 in close proximity to the active region 610. FIG. 7 illustrates another exemplary semiconductor test structure 700 including one or more multiple active jogs 715 such as, for example, a staircase active region jog 715a with narrow gate electrode extension forming an L-active region jog 715b, one or more gate electrodes 712 extended over the active region 710 onto the field oxide region 711, and substrate ground region 714 in close proximity to the active region 710. The test structure 700 can also include one or more H gate electrode turns over field dielectric region 718. In various embodiments, the semiconductor test structures 100, 200, 300, 400, 500, 600, 700 can be derived from SRAM device geometries known to cause current leakage path problems with older technology.

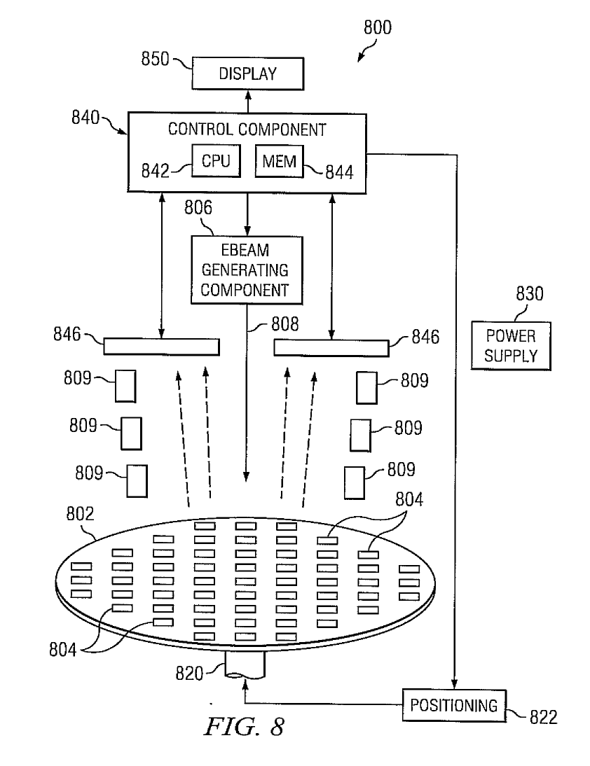

FIG. 8 illustrates an exemplary system 800 for detecting current leakage path defect formation during semiconductor processing. The system 800 can include a moveable stage 820 for mounting a semiconductor work piece 802, wherein the semiconductor work piece 802 can include one or more design elements sensitive to current leakage path formation and a substrate ground in close proximity to an active region. The moveable stage 820 can be coupled to a positioning component 822 that can move the semiconductor test structure 802. In some embodiments, the semiconductor work piece 802 can include a plurality of dies 804, wherein each die 804 can include one or more copies of integrated circuitry, each including one or more semiconductor test structures 100, 200, 300, 400, 500, 600, 700. In various embodiments, different areas (e.g. die) of the semiconductor work piece 802 can include the same integrated circuitry, therefore the beam 808 can be directed at a portion of the semiconductor work piece 802, such as, for example at a semiconductor test structures 100, 200, 300, 400, 500, 600, 700 to obtain one or more representative samplings. In some embodiments, transistors may be more densely concentrated in certain areas of the integrated circuitry, such as, for example, memory arrays, therefore it may be more efficient to sample these areas to detect current leakage path defect.

The system 800 can also include an electron beam microscope, disposed to direct an electron beam (e-beam) 808 at the semiconductor work piece 802 for producing a passive voltage contrast image thereof. One of ordinary skill in the art would know that in a voltage contrast image, various features emit electrons from their surface differently, thereby showing show different contrast levels (gray level values, GLV) if they are charged differently. In various embodiments, the electron beam microscope can include one or more guide components 809, such as, for example, electromagnets for containing the e-beam 808, directing the e-beam 808 towards the semiconductor work piece 802, and scanning the e-beam 808 across a portion of the semiconductor work piece 802. In some embodiments, the guide components 809 can focus the e-beam 808 to a size from about 0.0005 microns to about 0.2 microns. In various embodiments, the e-beam 808 can be directed at different locations of the work piece 802 by moving the work piece 802 and/or the e-beam 808 relative to one another. The term “component” as used herein is intended to include computer related entities, including one or more hardware devices, one or more software programs, a combination of one or more hardware devices and software programs, and software in execution. For example, a component may be a process running on a processor, a processor, an object, an executable, a thread of execution, a program, a computer, or any combination thereof. Both an application program running on a server and the server can be components.

The system 800 can also include one or more power supplies 830. In some embodiments, the power supply 830 can provide a high voltage to the e-beam generating component 806. In other embodiments, the power supply 830 can provide bias to the stage 820 to further attract the e-beam 808 towards the semiconductor work piece 802. In some other embodiments, the guide components 809 can be powered by the power supply to direct, contain and/or scan the e-beam 808.

The system 800 can also include a detector 846 to detect electrons emitted from the surface of the semiconductor test structure 802. As a result of the e-beam 808 striking the semiconductor work piece 802, secondary electrons (SE), back scattered electrons (BSE) as well as some other electrons, and photons are emitted out of the surface of the semiconductor work piece 802 and detected by the detector 846. The detector 846 can be biased accordingly by the power supply 830 to attract or repel these electrons. The voltage used for attracting or repelling secondary electrons and back scattered electrons is referred to as a “charge control voltage”. In some embodiments, the charge control voltage can be from about minus 300 Volts to about plus 2000 Volts.

The system 800 can also include an electronic control component 840. The electronic control unit 840 can be configured in any suitable manner to control and operate the various components of the system 800. The electronic control component 840 can include a processor 842, such as, for example, a microprocessor or CPU coupled to a memory 844. One of ordinary skill in the art would know that the processor can be programmed to carry out variety of functions, including, but not limited to controlling and operating various components of the system 800. The memory 844 can be used to store, among other things, one or more program codes to be executed by the processor 842. The memory 844 can include one or more read only memory (ROM) and random access memory (RAM). The ROM can include, among other codes, a Basic Input-Output System (BIOS) which can control the basic hardware operations of the system 800. The RAM can be the main memory and can include operating system and one or more application programs. The memory 844 can also be used as a temporary storage medium for storing information, such as, for example, tabulated data and algorithms. In some embodiments, the memory 844 can include a hard disk drive for mass data storage. The control component 840 receives signals from the detector 846 indicative of the electrons emitted from the wafer 802. These signals can then be used by the control component 840 to generate respective gray level values (GLV) for each of the scanned semiconductor work piece 802 location, where the brightness of a GLV for a particular location is a function of the number of electrons emitted from that location. In general, the higher the number of electrons emitted from a location and detected by the detector 846, the higher or brighter the corresponding GLV.

In an exemplary situation, the incident e-beam 808 can cause more electrons to be emitted than actually reach the detector 846, thereby inducing a positive charge on the surface of the semiconductor test structure 802. The positive surface potential can inhibit secondary electrons with low kinetic energy from leaving the surface, which in turn can cause fewer electrons to be detected by the detector 846. As a result, the resulting images can look dark or have low GLV relative to surrounding areas. However, the positive surface potential can be neutralized by electrons from lower regions in the substrate, so that the secondary electrons with low kinetic energy can escape and be detected by the detector 486.

In various embodiments, current leakage paths can be due to dislocations and/or pipes. The terms “pipe” and “dislocation pipe” as used herein refer to a dislocation with metal and/or metal derivatives in it. In various embodiments, metals and/or metal derivatives in the dislocation pipe can include, but are not limited to nickel, titanium, cobalt, platinum, and their silicides. The metal in the dislocation pipe can provide a pathway for electrons to migrate to the surface of the semiconductor test structure 802 to neutralize the accumulated positive charge. With the surface positive charge neutralized, more electrons can leave the surface of the test structure 802 and be detected by the detector 846, thereby yielding a brighter GLV. In various embodiments, in order to detect current leakage paths, the e-beam 808 can have a landing energy from about 1 Volt to about 1500 Volts, wherein the landing energy can be controlled by regulating the total bias between the e-beam generating component 806 and the semiconductor test structure 802 and/or stage 820. In some embodiments, the e-beam 808 current can be from about 1 nano Amp to about 3000 nano Amp, wherein the e-beam 808 current can be a function of an excitation voltage applied to the e-beam generating component 806 as well as the composition and/or composition of gases imparted into the e-beam generating component 806 among other things.

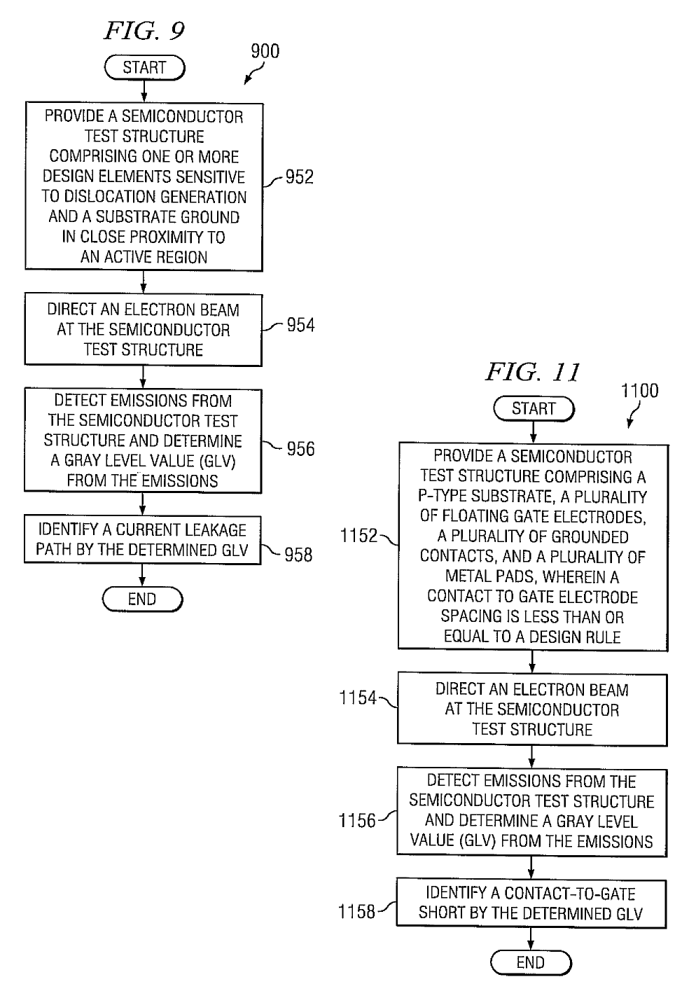

FIG. 9 is a flow diagram for a method 900 for detecting a current leakage path during semiconductor processing. The method 900 can include providing a semiconductor test structure comprising one or more design elements sensitive to current leakage path formation and a substrate ground in close proximity to an active region, as shown in step 952. In various embodiments, the step 952 of providing a semiconductor test structure including one or more design elements sensitive to current leakage path defect can include providing the semiconductor test structure with one or more of active layer jogs, double active jogs with asymmetry, multiple active jogs, poly turns on field, and H gate electrode turns over field dielectric regions. In some embodiments, the active layer jogs can include one or more of L-jogs, T-jogs, and U-jogs. In other embodiments, the multiple active jogs can include staircase layout. In some other embodiments, the gate electrode turns over field dielectric region can have various gate electrode to active region spacing and various gate electrode linewidths.

The method 900 for detecting a current leakage path defect during semiconductor processing can also include directing an electron beam at the semiconductor test structure, as in step 954. The method 900 can also include detecting emissions from the semiconductor test structure as a function of position along the scan direction and determining a gray level value (GLV) from the emissions as in step 956 and identifying an existence of a current leakage path by the determined GLV as shown in the step 958. In various embodiments, the current leakage path defect can be detected by comparing the determined GLV to a threshold GLV. In some embodiments, the determined GLV can be compared to GLV's for neighboring locations to identify a current leakage path. In other embodiments, if the determined GLV is brighter than respective neighboring GLV's, then the determined GLV correspond to a current leakage path. In various embodiments, if the determined GLV is brighter than respective neighboring GLV's in one or more adjacent die, then the determined GLV correspond to a current leakage path.

One of ordinary skill in the art would know that the semiconductor test structure goes through many processing stages during the semiconductor fabrication process, and that transistor formation is performed relatively early. Accordingly, the method can be implemented in early technology development before SRAM or other device circuitry, such as Logic circuitry layouts mature.

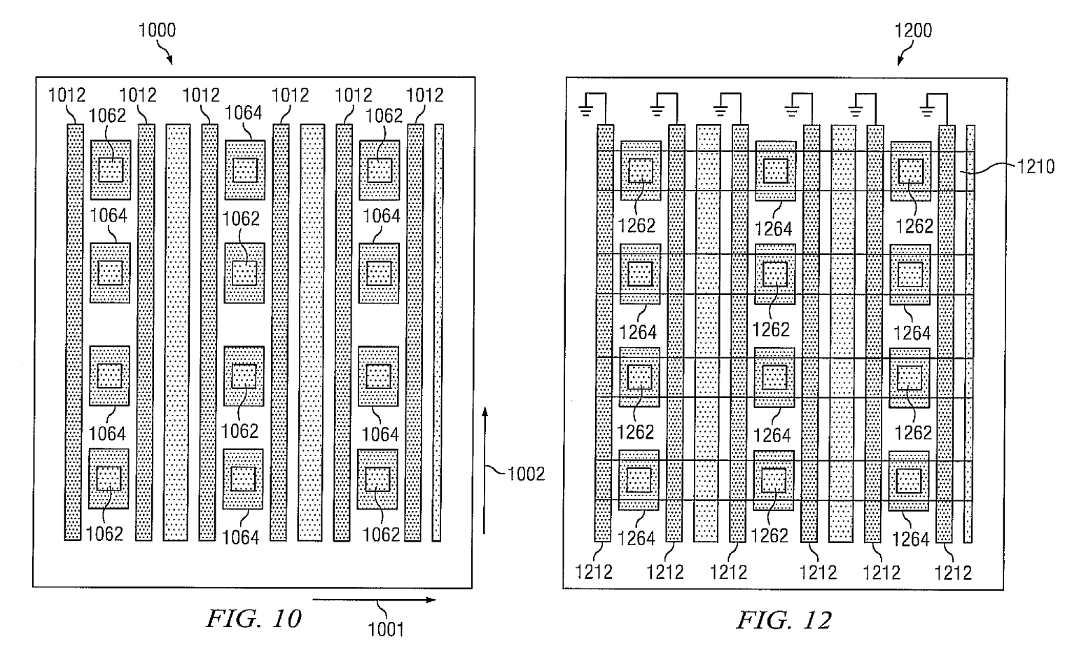

FIG. 10 illustrates a plan view of a portion of an exemplary semiconductor structure 1000 for detecting a contact-to-gate short. The semiconductor test structure 1000 can include a p-type substrate (not shown), a plurality of floating gate electrodes 1012, a plurality of grounded contacts 1062 passing through a dielectric layer (not shown), wherein a contact 1062 to gate electrode spacing can be less than or approximately equal to a design rule, and a plurality of metal pads 1064 over the dielectric layer (not shown) and connected to the grounded contact 1062. FIG. 10 also shows a first direction 1001 perpendicular to the gate electrodes 1012 and a second direction 1002 that can be perpendicular to the first direction 1001. In various embodiments, the design rule for contact to gate electrode spacing is approximately 35 nm for 45 nm technology. In some embodiments, the contact 1062 to gate electrode 1012 spacing in a semiconductor test structure can 1000 be about 30 nm. In other embodiments, the contact 1062 to gate electrode 1012 spacing in a semiconductor test structure 1000 can be about 28 nm. The reason for printing contacts 1062 spaced closer to gate electrodes 1012 than allowed by the design rule is to form a “canary” structure or a structure that is more sensitive to shorting than normally encountered for the perfect set of conditions. Thus, this canary structure can serve to estimate the risk that process variation, such as contact misalignment or contact size variation, can result in shorting. Also, one of ordinary skill in the art would know that contacts 1062 can be of any desired shape, such as, for example, square, round, etc.

FIG. 11 depicts a flow diagram of an exemplary method 1100 for detecting a contact-to-gate short during semiconductor processing. The method 1100 can include the step 1152 of providing a semiconductor test structure 1000 including a p-type substrate, a plurality of floating gate electrodes 1012, a plurality of grounded contacts 1062, and a plurality of metal pads 1064 connected to the grounded contacts 1062. The method 1100 for detecting a contact-to-gate short during semiconductor processing can further include directing an electron beam at the semiconductor test structure 1000, as in step 1154 and detecting emissions from the semiconductor test structure 1000 and determining a gray level value (GLV) from the emissions, as in step 1156. The method 1100 can further include identifying the contact-to-gate short by the determined GLV, as in step 1158. In various embodiments, the step 1154 of directing an electron beam at the semiconductor test structure 1000 can include scanning an electron beam along a first direction 1001 of the semiconductor test structure 1000, wherein the first direction 1001 is perpendicular to the direction of the floating gate electrodes 1012, as shown in FIG. 10. The step 1154 can also include detecting emissions from the semiconductor test structure 1000 and determining a gray level value (GLV) from the emissions and identifying a grounded gate electrode at a first location by the determined GLV, wherein the GLV of a grounded gate electrode is brighter than that of the floating gate electrode. The step 1154 can further include scanning the electron beam starting from the first location along a second direction 1002, wherein the second direction 1002 is perpendicular to the first direction 1001. In some embodiments, the step 1156 of detecting emissions from the semiconductor test structure 1000 can include detecting emissions from the semiconductor test structure 1000 along the second direction 1002 and determining a gray level value (GLV) from the emissions. In various embodiments, the method 1100 can include comparing the determined GLV to a threshold GLV to identify the contact-to-gate short. In some embodiments, the method 1100 can further include comparing the determined GLV to GLV's of neighboring locations to identify the contact-to-gate short. In other embodiments, the method 1100 can further include comparing the determined GLV to the neighboring GLV's in one or more adjacent dies to identify the contact-to-gate short. In various embodiments, the step 1154 of directing an electron beam at the semiconductor structure 1000 can include scanning an area. Area scans require more inspection time, but they are a viable strategy.

FIG. 12 illustrates a plan view of a portion of another exemplary semiconductor structure 1200 for detecting a contact-to-gate short. The semiconductor test structure 1200 can include a p-type substrate (not shown) including n-type active regions 1210, a plurality of grounded gate electrodes 1212, a plurality of floating contacts 1262 through a dielectric layer (not shown), wherein a contact 1262 to gate electrode 1212 spacing can be less than or equal to a design rule, and a plurality of metal pads 1264 over the dielectric layer (not shown) and connected to the floating contacts 1262. One of ordinary skill in the art would know that the design rule is the minimum allowed spacing of contacts to gate.

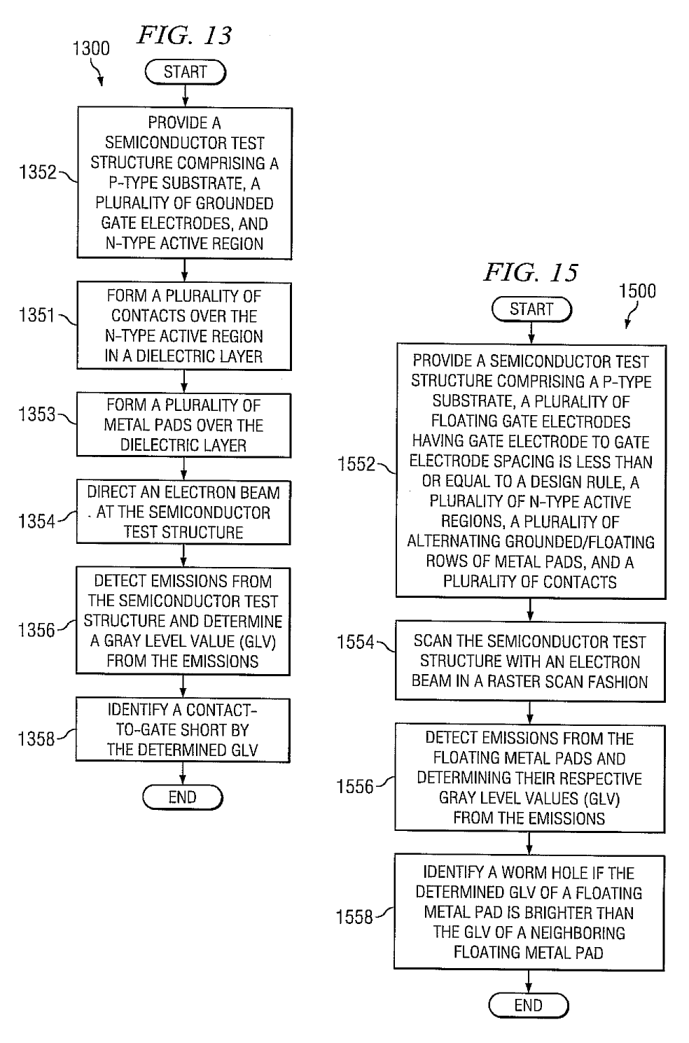

FIG. 13 depicts a flow diagram of another exemplary method 1300 for detecting a contact-to-gate short during semiconductor processing. The method 1300 can include providing a semiconductor test structure 1200 including a p-type substrate, a plurality of grounded gate electrodes 1212, and n-type active region 1210, as in step 1352. The method 1300 can further include forming a plurality of contacts 1262 through a dielectric layer (not shown) over the n-type active region 1210, wherein a contact 1262 to gate electrode 1212 spacing is less than or equal to a design rule as in step 1351, and forming a plurality of metal pads 1264 over the dielectric layer (not shown) and connected to the floating contacts 1262, as in step 1353. The method 1300 for detecting a contact-to-gate short during semiconductor processing can further include directing an electron beam at the semiconductor test structure 1200, as in step 1354. In some embodiments, the step 1354 of directing an electron beam at the semiconductor test structure 1200 can include directing the electron beam over the plurality of contacts 1262 before the step 1353 of forming metal pads. The method 1300 as shown in FIG. 13 can further include detecting emissions from the plurality of contacts 1262 of the semiconductor test structure 1200 and determining a gray level value (GLV) from the emissions, as in step 1356, and determining whether a contact-to-gate short exists using the determined GLV, as in step 1358. In various embodiments, the method 1300 can also include comparing the determined GLV to a threshold GLV to identify the contact-to-gate short. In some embodiments, the method 1300 can include comparing the determined GLV to GLV's of neighboring locations to identify the contact-to-gate short. In other embodiments, the method 1300 can include comparing the determined GLV to neighboring GLV's in one or more adjacent dies to identify the contact-to-gate short. Yet, in some other embodiments, the method 1300 can further include determining if the determined GLV is brighter than respective neighboring GLV's to identify the contact-to-gate short.

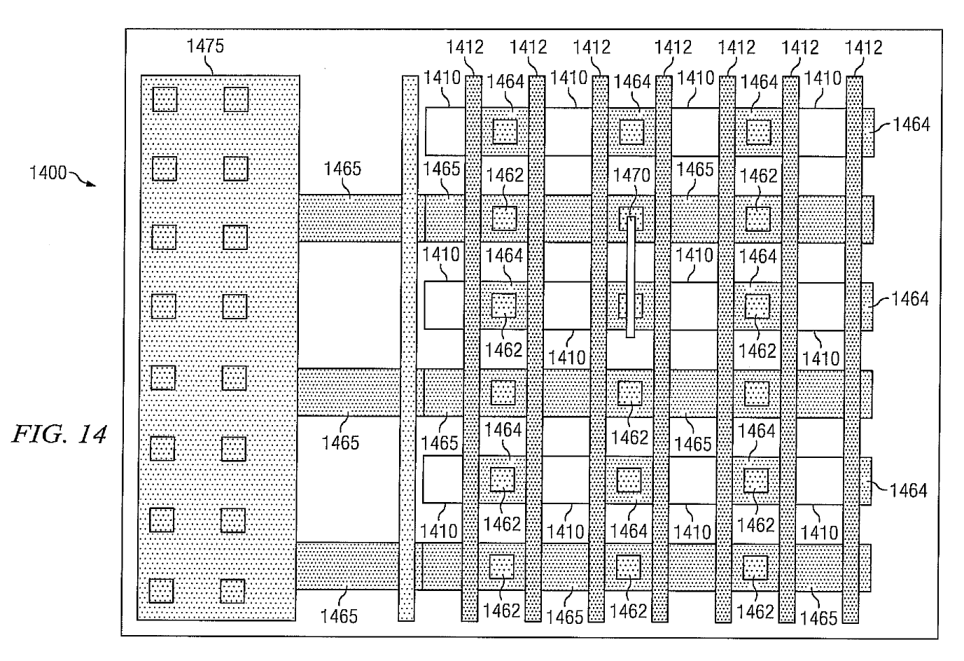

FIG. 14 illustrates a plan view of a portion of an exemplary semiconductor test structure 1400 for detecting a worm hole 1470 in accordance with the present teachings. As used herein, the term “worm hole” refers to a leakage path existing between two topographical steps which are covered by a film such as a dielectric. Worm holes can form when the dielectric deposition does not completely seal the center area between the two topographical steps, leaving either a microscopic void or a micro-crack, running parallel to the step. Such a structural weakness in the overlying dielectric provides a path for metal migration. The metal can be tungsten deposited to fill contacts. When subjected to temperatures greater than about 300° C., the tungsten can migrate into the dielectric seams, forming an electrically conducting path from one contact to another. The semiconductor structure 1400 for detecting worm-holes 1470 can include a p-type substrate (not shown) including a plurality of n-type active regions 1410 and a plurality of gate electrodes 1412 wherein a gate electrode 1412 to gate electrode 1412 spacing is less than or equal to a design rule. In various embodiments, the design rule for gate electrode 1412 to gate electrode 1412 spacing can be about 130 nm for 45 nm technology. However, the design rule for gate electrode 1412 to gate electrode 1412 spacing can be smaller than 130 nm for sub-45 nm technology. In some embodiments, the semiconductor test structure 1400 can have the gate electrode 1412 to gate electrode 1412 spacing from about 118 nm to about 124 nm for 45 nm technology. The semiconductor structure 1400 can further include a plurality of contacts 1462 through a dielectric layer (not shown) and a plurality of alternating grounded rows of metal pads 1465 and floating rows of metal pads 1464 over the dielectric layer (not shown), wherein each of the contacts 1462 is connected either to the floating metal pad 1464 or grounded metal pad 1465. In various embodiments, the semiconductor structure 1400 can also include a ground pad 1475 as shown in FIG. 14.

FIG. 15 depicts a flow diagram of an exemplary method 1500 for detecting a worm-hole during semiconductor processing. The method 1500 can include a step 1552 of providing a semiconductor test structure 1400 including a p-type substrate (not shown), a plurality of gate electrodes 1412 having a gate electrode 1412 to gate electrode 1412 spacing of equal to or less than a design rule, a plurality of n-type active regions 1410, a plurality of alternating grounded/floating rows of metal pads 1465, 1464, and a plurality of contacts 1462, as shown in FIG. 15. The method 1500 can also include scanning the semiconductor test structure 1400 with an electron beam in a raster scan fashion, as in step 1554. One of ordinary skill in the art would know that in a raster scan fashion, the electron beam scans first in one direction and then moves incrementally in the perpendicular direction before scanning in the original direction at a position offset from the first scan. The method 1500 can further include detecting emissions from the floating metal pads 1464 and determining their respective gray level values (GLV) from the emissions, as in step 1556, wherein the GLV of a grounded metal pad 1465 is brighter than the GLV of the floating metal pads 1464. The method 1500 can also include identifying a worm hole if the determined GLV of a floating metal pad 1464 is brighter than the GLV of a neighboring floating metal pad 1464, as shown in step 1558. In some embodiments, the step of identifying a worm hole comprises determining if the determined GLV of a floating metal pad is brighter than respective neighboring GLV's of the floating metal pads in one or more adjacent dies.

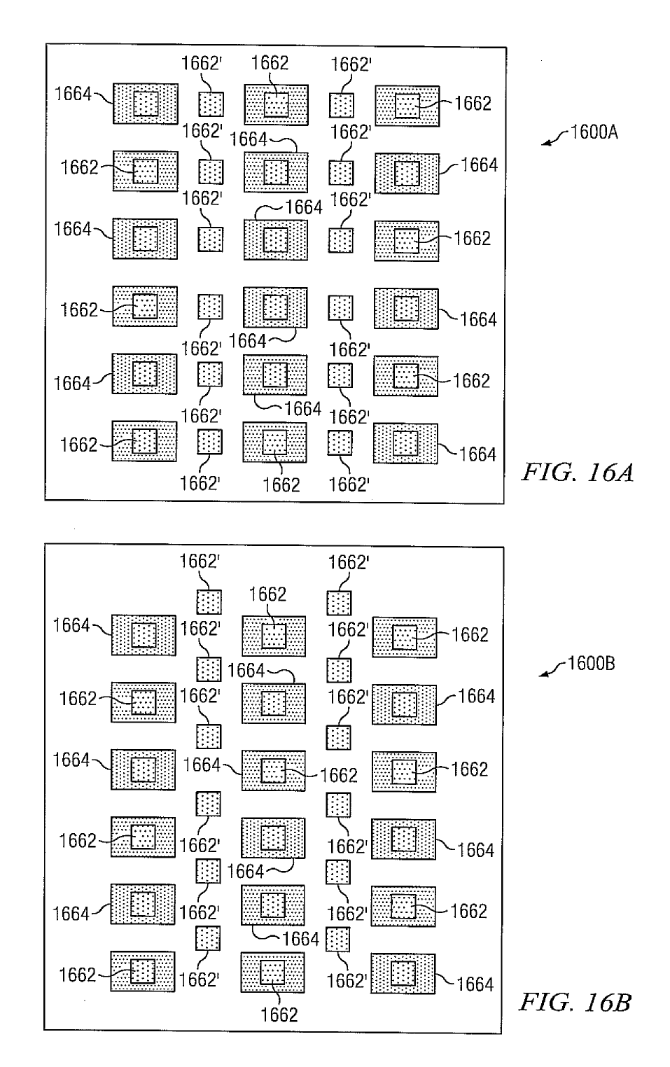

FIGS. 16A and 16B illustrate exemplary semiconductor test structures 1600A, 1600B for detecting troublesome pitches for hole printing during semiconductor processing. As used herein, the term ‘hole printing’ refers to forming a contact or a via in an integrated circuit device, wherein forming a hole in a resist layer is the first step. A contact is a hole in a dielectric that when filled with a conductor such as tungsten makes an electrical contact with an underlying non-metal region, such as an active area or gate conductor, while a via is a hole in a dielectric that when filled with a conductor such as aluminum, copper, or an alloy of aluminum & copper makes an electrical contact with a metallic under layer. Hence the term “hole” will be used herein to refer to a contact or a via. Furthermore, as used herein the term “troublesome pitch” refers to a contact separation distance suspected to present patterning difficulties based on photolithographic modeling. Such troublesome pitches can arise in printing arrays or sub-arrays of holes spaced periodically from each other. One of ordinary skill in the art would know that the exact values of troublesome pitches depend on nature of the photolithographic tools and processes used to print holes. The exemplary semiconductor test structures 1600A, 1600B can include a p-type substrate (not shown), a dielectric layer (not shown) over the substrate (not shown), an array of grounded holes 1662, 1662′ through the dielectric layer having a desired troublesome, and a plurality of metal pads 1664 over the dielectric layer and connected to the grounded holes 1662, 1662′. In some embodiments, the troublesome pitch is determined by one or more of an exposure conditions modeling and an empirical data. In various embodiments, the array of grounded holes 1662, 1662′ having a desired troublesome pitch can include one or more of a 165 nm by 165 nm array; a 170 nm by 170 nm array; a 170 nm by 280 nm array; a 170 nm by 330 nm staggered array; a 280 nm by 280 nm array; a 330 nm by 330 nm staggered array; a 410 nm by 410 nm array; a 410 nm by 410 nm staggered array; a 540 nm by 540 nm array; and a 540 nm by 540 nm staggered array. The numbers A and B in the A by B array refer to the hole spacing of A nm and B nm, which photolithographic models define as a potentially troubling pitch for 45 nm integrated circuit technology. Other sets of design rules for different technology generations can have the same or different sets of troublesome pitches. Additionally, different photolithography tools and processes can result in a different set of troublesome pitches. FIG. 16A depicts a portion of a 165 nm by 165 nm array. As can be seen in FIG. 16A, in a normal array, holes are printed at the corners of rectangles with the rectangles being placed side by side in both x and y directions. FIG. 16B depicts a portion of a 170 by 330 staggered array, wherein the staggered array is the superposition of two normal arrays, one offset from the other by half the repeat distance in the x direction and half of the repeat distance in the y direction. In various embodiments, some of the plurality of grounded holes 1662 can include a metal pad, whereas the rest of the grounded holes 1662′ can be without metal pad.

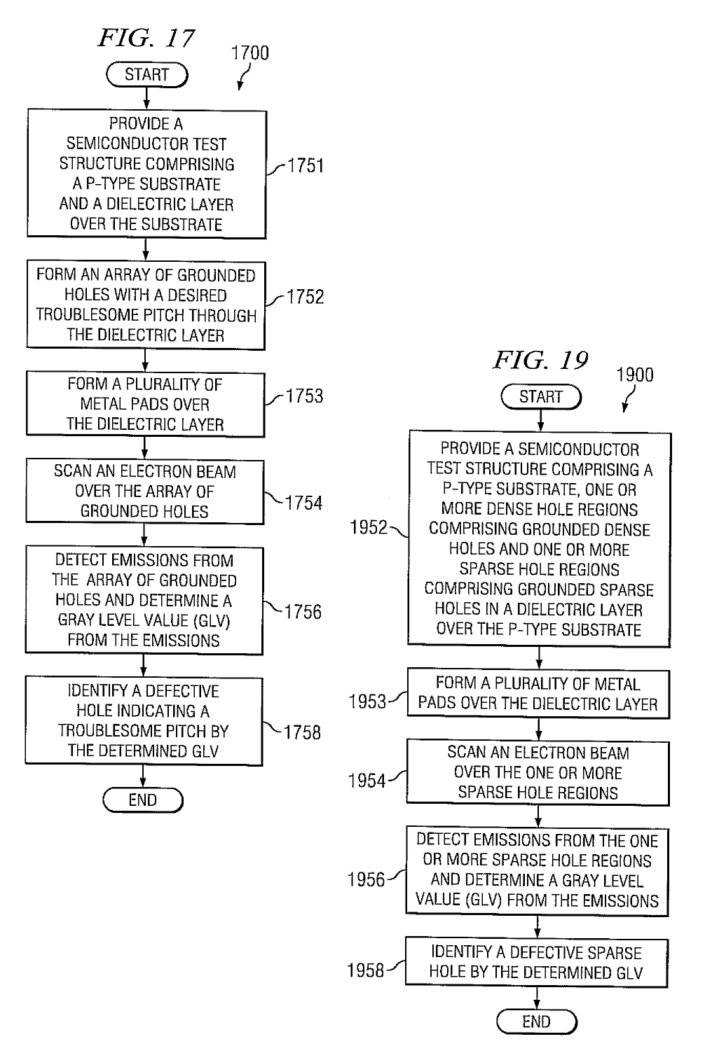

FIG. 17 depicts a flow diagram of an exemplary method 1700 for detecting troublesome pitches for hole printing during semiconductor processing. The method 1700 can include providing a semiconductor test structure including a p-type substrate, and a dielectric layer over the substrate, as in step 1751. The method 1700 can also include forming an array of grounded holes through the dielectric layer with a desired troublesome pitch, as in step 1752, wherein the troublesome pitch is determined by one or more of an exposure conditions modeling and an empirical data. The method 1700 can also include forming a plurality of metal pads over the dielectric layer and connected to the grounded holes, as in step 1753. In various embodiments the desired troublesome pitch can include one or more of a 165 nm by 165 nm array; a 170 nm by 170 nm array; a 170 nm by 280 nm array; a 170 nm by 330 nm staggered array; a 280 nm by 280 nm array; a 330 nm by 330 nm staggered array; a 410 nm by 410 nm array; a 410 nm by 410 nm staggered array; a 540 nm by 540 nm array; and a 540 nm by 540 nm staggered array. The method 1700 can further include scanning an electron beam over the array of grounded holes, as in step 1754, detecting emissions from the semiconductor test structure, and determining a gray level value (GLV) from the emissions, as shown in step 1756. In some embodiments, the step 1754 of scanning an electron beam over the array of grounded holes can include directing the electron beam over the array of grounded holes before the step 1753 of forming metal pads. In other embodiments, the step 1754 of scanning an electron beam over the array of grounded holes can include directing the electron beam over the metal pads. The method 1700 can also include identifying a defective hole indicating a troublesome pitch by the determined GLV, as in step 1758. In various embodiments, the method 1700 can also include comparing the determined GLV to a threshold GLV to identify a defective hole indicating the troublesome pitch. In some embodiments, the method 1700 can include comparing the determined GLV to GLV's of neighboring locations to identify the defective hole and hence troublesome pitch. In some embodiments, the method 1700 can include comparing the determined GLV to neighboring GLV's in one or more adjacent dies to identify the defective hole and hence troublesome pitch. In other embodiments, the method 1700 can include determining if the determined GLV is darker than respective neighboring GLV's to identify the defective hole indicating the troublesome pitch. In various embodiments, the step 1758 of identifying a defective hole corresponding to a trouble pitch can include identifying one or more of smaller than normal holes, deformed holes, and missing holes.

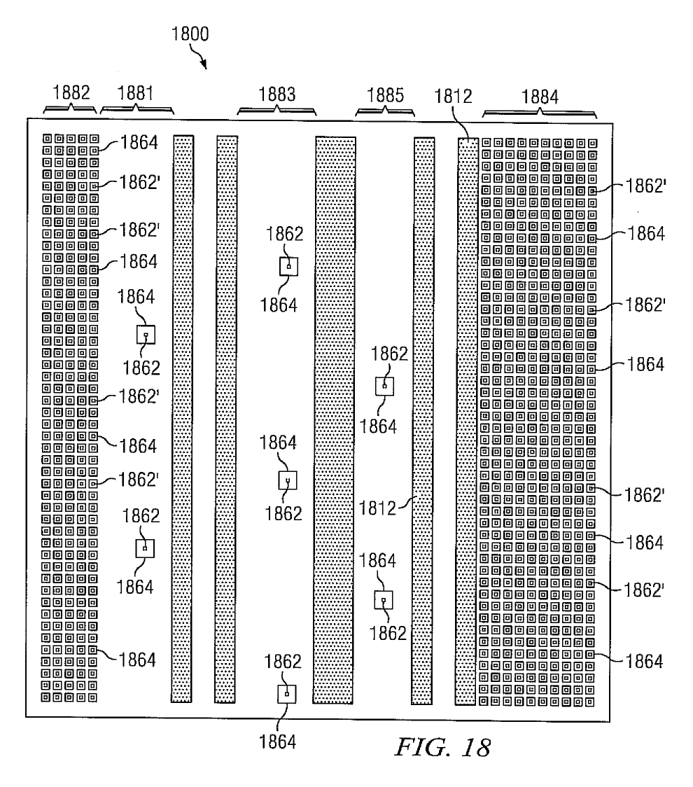

FIG. 18 illustrates a plan view of a portion of an exemplary semiconductor test structure 1800 for detecting anomalies in sparse holes during semiconductor processing. As used herein, the term “sparse hole” refers to a hole (via or contact) located in a region with much lower than normal hole density. For example, in 32 nm technology the hole density of the densest designs is in the range of about 30 to about 100 holes per square micron. A region of an integrated circuit design could be considered to have a sparse hole region if it contains holes with density in the range of about 0.01 to about 5 holes per square micron. The semiconductor test structure 1800 can include a p-type substrate, one or more dense hole regions including dense holes 1862′ through a dielectric layer (not shown) over the p-type substrate (not shown). The semiconductor test structure 1800 can also include one or more sparse hole regions including grounded sparse holes 1862 through the dielectric layer (not shown) over the p-type substrate (not shown). FIG. 18 shows exemplary semiconductor test structure 1800 including two dense hole regions, a first region 1882 and a second region 1884 of dense holes 1862′ and three sparse hole regions, a third region 1881 of sparse holes 1862 at a first distance from the first region 1882, a fourth region 1883 of sparse holes 1862 at a second distance from the first region 1882, and a fifth region 1885 of sparse holes 1862 at a third distance from the second region 1884. In various embodiments, the semiconductor structure 1800 can include metal pads 1864 over the dielectric layer and connected to the grounded sparse holes 1862. In various embodiments, the first distance can be from about 0 to about 3 μm, the second distance can be from about 1 μm to about 6 μm, and the third distance can be from about 2 μm to about 15 μm.

FIG. 19 depicts a flow diagram of an exemplary method 1900 for detecting anomalies in sparse holes during semiconductor processing. The method 1900 can include providing a semiconductor test structure including a p-type substrate (not shown), one or more dense hole regions 1882, 1884 including dense holes 1862′, and one or more sparse hole regions 1881, 1883, 1885 including sparse holes 1862 through a dielectric layer (not shown) over the p-type substrate, wherein the dense holes 1862′ and the sparse holes 1862 can be grounded, as shown in step 1952. The method 1900 can further include forming a plurality of metal pads over the dielectric layer and connected to the grounded sparse holes, as in step 1953 and scanning an electron beam over the one or more sparse hole regions 1881, 1883, 1885, as in step 1954. In various embodiments, the step 1954 of scanning an electron beam over the one or more sparse hole regions 1881, 1883, 1885 can include scanning an electron beam over the one or more sparse hole regions 1881, 1883, 1885 before the step 1953 of forming metal pads 1864. The method 1900 for detecting anomalies in sparse holes can further include detecting emissions from the one or more sparse hole regions 1881, 1883, 1885 and determining a gray level value (GLV) from the emissions, as in step 1956 and identifying a defective sparse hole 1862 by the determined GLV, as in step 1958. In various embodiments, the step 1958 of identifying a defective sparse hole 1862 can include identifying one or more of smaller than normal holes, deformed holes, and missing holes. In some embodiments, the method 1900 can further include comparing the determined GLV to a threshold GLV to identify the defective sparse hole. In other embodiments, the method 1900 can include comparing the determined GLV to GLV's for neighboring sparse hole to identify the defective sparse hole. In various embodiments, the method 1900 can include comparing the determined GLV to neighboring GLV's in one or more adjacent dies to identify the defective sparse hole. Yet, in some other embodiments, the method 1900 can include determining whether the determined GLV is darker than a respective neighboring GLV's to identify the defective sparse hole.

While the invention has been illustrated respect to one or more implementations, alterations and/or modifications can be made to the illustrated examples without departing from the spirit and scope of the appended claims. In addition, while a particular feature of the invention may have been disclosed with respect to only one of several implementations, such feature may be combined with one or more other features of the other implementations as may be desired and advantageous for any given or particular function. Furthermore, to the extent that the terms “including”, “includes”, “having”, “has”, “with”, or variants thereof are used in either the detailed description and the claims, such terms are intended to be inclusive in a manner similar to the term “comprising.” As used herein, the phrase “X comprises one or more of A, B, and C” means that X can include any of the following: either A, B, or C alone; or combinations of two, such as A and B, B and C, and A and C; or combinations of three A, B and C.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A method for detecting a defect during semiconductor processing comprising:
providing a semiconductor test structure;
directing an electron beam at the semiconductor test structure;
detecting emissions from the semiconductor test structure and determining a gray level value (GLV) from the emissions; and
identifying a defect by the determined GLV.

2. The method of claim 1, wherein the defect is one or more of contact-to-gate shorts, worm hole leakage paths, holes printing issues, anomalies in sparse holes, and current leakage paths due to dislocations and pipes.

3. The method of claim 1 further comprising comparing the determined GLV to a threshold GLV to identify the defect.

4. The method of claim 1 further comprising comparing the determined GLV to GLV's for neighboring locations to identify the defect.

5. The method of claim 1 further comprising comparing the determined GLV to neighboring GLV's in one or more adjacent dies to identify the defect.

6. The method of claim 1, wherein the step of providing a semiconductor test structure comprises providing a semiconductor test structure comprising one or more design elements sensitive to current leakage path formation, wherein the semiconductor structure comprises:
one or more of active layer jogs, double active jogs with asymmetry, multiple active jogs, gate electrode turns over field dielectric regions, and H gate electrode turns over field dielectric regions, wherein the active layer jogs comprise one or more of L-jogs, T-jogs, and U-jogs and the multiple active jogs comprise a staircase layout;
a substrate ground in close proximity to an active region comprising one or more of remote substrate grounds and substrate ground regions preserving gate periodicity; and
a plurality of gate electrodes having one or more spacing between the gate electrode and the active region.

7. The method of claim 1, wherein the step of providing a semiconductor test structure comprises providing a semiconductor test structure for detecting a contact-to-gate short comprising a p-type substrate, a plurality of floating gate electrodes, a plurality of grounded contacts, and a plurality of metal pads, wherein a contact to gate electrode spacing is less than or equal to a design rule.

8. The method of claim 7, wherein the step of directing an electron beam at the semiconductor test structure comprises:
scanning an electron beam along a first direction of the semiconductor test structure, wherein the first direction is perpendicular to the direction of the floating gate electrodes;
detecting emissions from the semiconductor test structure along the first direction and determining a first gray level value (GLV) from the emissions;
identifying a grounded gate electrode at a first location by the determined first GLV, wherein the GLV of the grounded gate electrode is brighter than that of the floating gate electrode; and
scanning the electron beam starting from the first location along a second direction, wherein the second direction is perpendicular to the first direction.

9. The method of claim 8, wherein the step of detecting emissions from the semiconductor test structure comprises detecting emissions from the semiconductor test structure along the second direction and determining a gray level value (GLV) from the emissions as a function of distance or position along the second direction.

10. The method of claim 1, wherein the step of providing a semiconductor test structure comprises providing a semiconductor test structure for detecting a contact-to-gate short comprising a p-type substrate comprising n-type active regions, a plurality of grounded gate electrodes, a plurality of floating contacts through a dielectric layer over the n-type active region, and a plurality of metal pads over the dielectric layer, wherein a contact to gate electrode spacing is less than or equal to a design rule.

11. The method of claim 1, wherein the step of providing a semiconductor test structure comprises providing a semiconductor test structure for detecting a worm-hole comprising a p-type substrate, a plurality of gate electrodes having a gate electrode to gate electrode spacing of less than or equal to a design rule, a plurality of n-type active regions, a plurality of contacts through a dielectric layer, and a plurality of alternating grounded/floating rows of metal pads.

12. The method of claim 11, wherein the step of identifying a defect by the determined GLV comprises identifying a worm hole if the determined GLV of a floating metal pad is brighter than the GLV of a neighboring floating metal pad.

13. The method of claim 1, wherein the step of providing a semiconductor test structure comprises:
providing a semiconductor test structure for detecting troublesome pitches for hole printing during semiconductor processing comprising a p-type substrate, and a dielectric layer over the substrate,
forming an array of grounded holes through the dielectric layer with a desired troublesome pitch, wherein the troublesome pitch is determined by one or more of an exposure conditions modeling and an empirical data; and
forming a plurality of metal pads over the dielectric layer.

14. The method of claim 13, wherein the step of directing an electron beam at the semiconductor test structure comprises directing the electron beam over the grounded holes before the step of forming metal pads.

15. The method of claim 13, wherein the step of identifying a defect by the determined GLV comprises identifying one or more of smaller than normal holes, deformed holes, and missing holes indicating a troublesome pitch by the determined GLV, wherein the determined GLV of the smaller than normal hole, deformed hole, and missing hole is darker than respective neighboring GLV's.

16. The method of claim 1, wherein the step of providing a semiconductor test structure comprises:
providing a semiconductor test structure for detecting anomalies in sparse holes during semiconductor processing comprising a p-type substrate, one or more dense hole regions comprising a plurality of grounded dense holes, and one or more sparse hole regions comprising a plurality of grounded sparse holes through a dielectric layer over the p-type substrate; and
forming a plurality of metal pads over the dielectric layer.

17. The method of claim 16, wherein the step of identifying a defect by the determined GLV comprises identifying one or more defective sparse holes, wherein the defective sparse holes comprises one or more of smaller than normal holes, deformed holes, and missing holes and wherein the determined GLV of the defective sparse hole is darker than respective neighboring GLV's.

18. The method of claim 16, wherein the step of scanning an electron beam over the one or more sparse hole regions comprises scanning the electron beam over the one or more sparse hole regions before the step of forming metal pads.

19. A semiconductor test structure for detecting current leakage paths comprising:
one or more design elements accentuating localized, non-uniform stress in a semiconductor device, selected from the group consisting of active layer jogs, double active jogs with asymmetry, multiple active jogs, gate electrode turns over field dielectric regions, and H gate electrode turns over field dielectric regions; and
a substrate ground in close proximity to an active region comprising one or more of remote substrate grounds and substrate ground regions preserving gate periodicity; and
a plurality of gate electrodes having one or more spacing between the gate electrode and the active region.

20. The semiconductor test structure of claim 19, wherein the active layer jogs comprise one or more of L-jogs, T-jogs, and U-jogs.

21. The semiconductor test structure of claim 19, wherein the multiple active jogs comprise a staircase layout.

22. A semiconductor test structure for detecting a contact-to-gate short comprising:
a p-type substrate;
a plurality of floating gate electrodes;
a plurality of grounded contacts through a dielectric layer, wherein a contact to gate electrode line spacing is less than or equal to a design rule; and
a plurality of metal pads over the dielectric layer.

23. A semiconductor test structure for detecting a worm-hole during semiconductor processing comprising:
a p-type substrate comprising a plurality of n-type active regions;
a plurality of gate electrodes wherein a gate electrode to gate electrode spacing is less than or equal to a design rule;
a plurality of contacts through a dielectric layer; and
a plurality of alternating grounded/floating rows of metal pads over the dielectric layer.

24. A semiconductor test structure for detecting troublesome pitches for hole printing during semiconductor processing comprising:
a p-type substrate;
a dielectric layer over the substrate,
an array of grounded holes through the dielectric layer having a desired troublesome pitch, wherein the troublesome pitch is determined by one or more of an exposure conditions modeling and an empirical data; and
a plurality of metal pads over the dielectric layer.

25. The semiconductor test structure of claim 24, wherein the array of grounded holes through the dielectric layer having a desired troublesome pitch comprises one or more of a 165 nm by 165 nm array; a 170 nm by 170 nm array; a 170 nm by 280 nm array; a 170 nm by 330 nm staggered array; a 280 nm by 280 nm array; a 330 nm by 330 nm staggered array; a 410 nm by 410 nm array; a 410 nm by 410 nm staggered array; a 540 nm by 540 nm array; and a 540 nm by 540 nm staggered array.
